(19) United States
(12) Patent Application Publication
(10) Pub. No.: US 2025/0221182 A1
(43) Pub. Date: Jul. 3, 2025

(54) ORGANIC LIGHT EMITTING DISPLAY PANEL

(71) Applicant: LG Display Co., Ltd., Seoul (KR)

(72) Inventors: Chang Hwan KWAK, Paju-si (KR); Jin Ho PARK, Paju-si (KR)

(73) Assignee: LG Display Co., Ltd., Seoul (KR)

(21) Appl. No.: 18/979,353

(22) Filed: Dec. 12, 2024

(30) Foreign Application Priority Data
Dec. 29, 2023 (KR) 10-2023-0197844

(51) Int. Cl. H10K 59/123; G09G 3/20; G09G 3/3233; H10K 50/13; H10K 50/17; H10K 50/19; H10K 59/122; H10K 59/35; H10K 59/80

(52) U.S. Cl. CPC H10K 59/123; G09G 3/2074; G09G 3/3233; H10K 50/131; H10K 50/17; H10K 50/171; H10K 50/19; H10K 59/122; H10K 59/80516; G09G 2300/0804; G09G 2300/0819; G09G 2300/0871; G09G 2310/08; G09G 2320/0247; H10K 59/352

(57) ABSTRACT

Discussed is a display panel including a substrate, a circuit layer disposed on the substrate, and a light emitting element layer disposed on the circuit layer and electrically connected to a pixel circuit of the circuit layer. The light emitting element layer includes a first electrode and a second electrode electrically connected to the pixel circuit, a first light emitting layer, a charge generating layer, and a second light emitting layer stacked on the first electrode, and a third electrode disposed on the second light emitting layer. The second electrode can supply a voltage to the charge generation layer that is different from those supplied to the first electrode and the third electrode.

### CROSS-REFERENCE TO RELATED APPLICATION

This application claims priority to Korean Patent Application No. 10-2023-0197844, filed in the Republic of Korea on Dec. 29, 2023, the entire contents of which is hereby expressly incorporated by reference into the present application.

### BACKGROUND

### 1. Field of the Invention

Embodiments relate to a display panel using an organic light emitting diode as a light source.

### 2. Discussion of the Related Art

Among various display devices, an electroluminescent display device are able to display images using self-luminous elements, because the electroluminescent display device does not require a separate light source, such as a backlight unit. The ability to be self-luminous can enable the electroluminescent display device to be implemented in various thin forms.

The types of electroluminescent display device includes an organic light emitting display device in which an organic light emitting diode (hereinafter referred to as an “OLED”) is disposed, and an inorganic light emitting display device (hereinafter referred to as an “LED display device”) in which an inorganic light emitting diode (hereinafter referred to as an “LED”) is disposed, among others.

The OLED display device includes an organic light emitting layer in which electrons and holes are combined to emit visible light. Recently, research has been actively conducted on OLED display devices with a tandem structure that are manufactured by stacking a plurality of organic light emitting layers to generate either a same light or different lights from the tandem structure. Tandem structured OLED display devices can be suitable for implementing large screen OLED display devices because of their high efficiency and improved lifetime characteristics.

In addition, stack-type organic light emitting elements have different light emitting layers in each stack, which emit light of a plurality of colors, between positive and negative electrodes, and a charge generating layer is provided between the stacks, and thus the stacks are separated by the charge generating layer.

### SUMMARY OF THE DISCLOSURE

In an organic light emitting display panel in which such a tandem method is applied, a flashing phenomenon can be visible at low grayscale due to fluctuations in the potential of a charge generating layer.

Objects of the present disclosure are not limited to those mentioned above, and other objects not mentioned here will be clearly understood by those skilled in the art from the following description.

There is provided a display panel including a substrate, a circuit layer disposed on the substrate, and a light emitting element layer disposed on the circuit layer and electrically connected to a pixel circuit of the circuit layer, wherein the light emitting element layer includes a first electrode and a second electrode electrically connected to the pixel circuit, a first light emitting layer, a charge generating layer, and a second light emitting layer stacked on the first electrode and the second electrode, and a third electrode disposed on the second light emitting layer.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a block diagram showing a display device according to an embodiment of the present disclosure.

FIG. 2 is a block diagram schematically showing a configuration of a drive IC.

FIG. 3 is a cross-sectional view showing a cross-sectional structure of a sub-pixel in a display panel according to an embodiment of the present disclosure.

FIG. 4 is a cross-sectional view showing in detail a cross-sectional structure of a light emitting element according to an embodiment of the present disclosure.

FIG. 5 is a cross-sectional view showing in detail a tandem structure of an organic light emitting element according to an embodiment of the present disclosure.

FIG. 6 is a view showing a driving circuit diagram of a display panel according to an embodiment of the present disclosure.

FIG. 7 is a view showing an example of a voltage applied to a light emitting element at low grayscale.

FIG. 8 is a plan view showing an example of light emitting areas for each color of sub-pixels according to various embodiments of the present disclosure.

### DETAILED DESCRIPTION OF THE EMBODIMENTS

Advantages and features of the present invention, and methods of achieving them, will become clear by referring to embodiments described in detail below along with accompanying drawings. The present invention is not limited to the embodiments disclosed below and can be implemented in various different forms, and these embodiments are merely provided to make the disclosure of the present invention complete and fully inform those skilled in the art to which the present invention pertains of the scope of the present invention, and the present invention is only defined by the scope of the appended claims.

Since shapes, sizes, ratios, angles, numbers, and the like disclosed in the drawings for describing the embodiments of the present invention are illustrative, the present invention is not limited to the illustrated items. The same reference number indicates the same components throughout the disclosure. In addition, in describing the present invention, when it is determined that the detailed description of a related known technology can unnecessarily obscure the gist of the present invention, the detailed description thereof will be omitted.

When the terms “comprise,” “include,” “have,” and “consist of” described in the present disclosure are used, other parts can be added unless “only” is used. When a component is expressed in the singular, it can be interpreted as a plurality of components unless specifically stated otherwise.

When interpreting a component, it is interpreted to include a margin of error unless otherwise specifically stated.

When a position relationship and interconnection relationship between two components, such as “on,” “above,” “under,” “next to,” “connected or coupled,” “crossing or intersecting,” or the like is described, one or more other components can be interposed between the components unless the term “immediately” or “directly” is used.

When a temporal relationship is described using the term “after,” “subsequently,” “then,” “before,” or the like, it can include a non-continuous case unless the term “immediately” or “directly” is used.

To distinguish components, the term “first,” “second,” and the like can be used in front of the names of the components, but functions or structures thereof are not limited by the ordinal numbers or component names. For convenience of description, the ordinal number attached to the names of the same components can be different between embodiments.

The term “can” fully encompasses all the meanings and coverages of the term “may.”

The term “made of” for an element can fully encompass the meaning of being completely formed of the element, or simply including the element.

The following embodiments can be partially or fully coupled or combined, and various technological interconnections and operations are possible. The embodiments can be implemented independently of each other and implemented together in an associated relationship.

Hereinafter, various embodiments of the present invention will be described in detail with reference to the accompanying drawings.

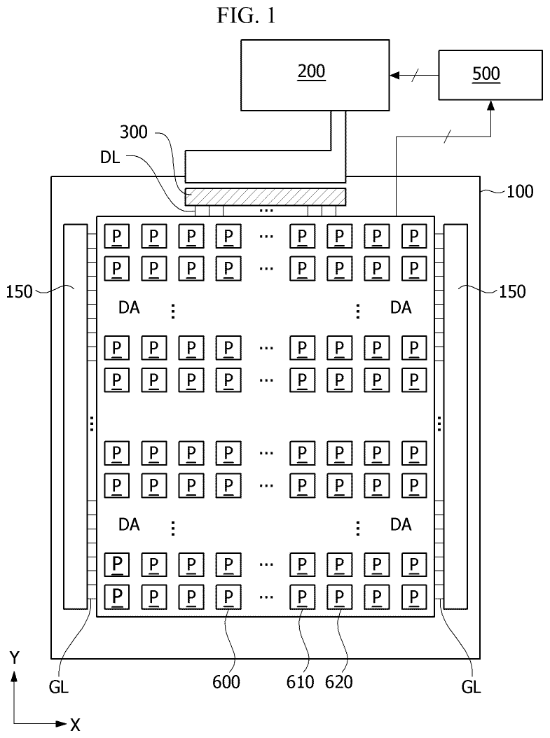

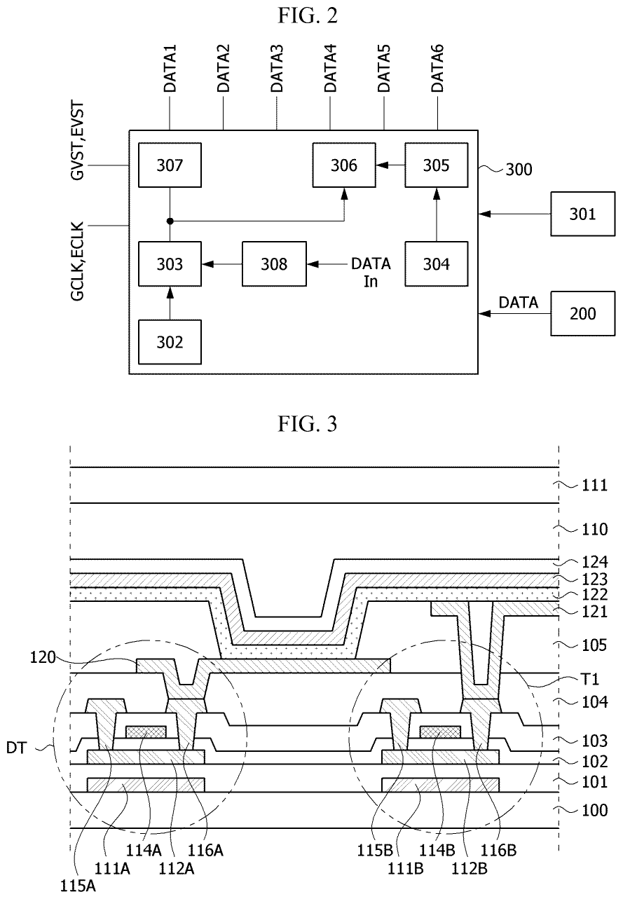

FIG. 1 is a block diagram showing a display device according to an embodiment of the present invention. FIG. 2 is a block diagram schematically showing a configuration of a drive IC. All components of each display device or drive IC according to all embodiments of the present disclosure are operatively coupled and configured.

Referring to FIGS. 1 and 2, the display device includes a substrate 100 on which a pixel array is disposed on a screen, a display panel driver, etc.

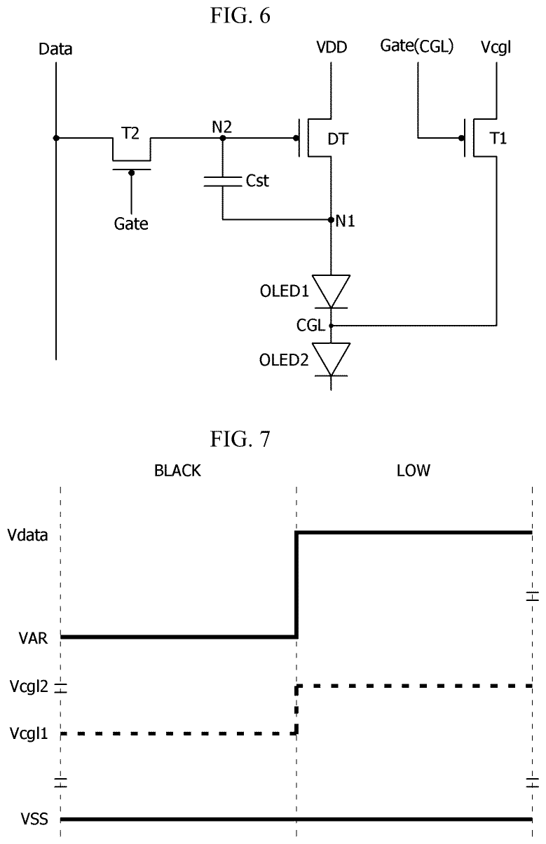

The pixel array of the substrate 100 includes data lines DL, gate lines GL intersecting the data lines DL, and display pixels P arranged in a matrix form defined by the data lines DL and the gate lines GL. The pixel array further includes power lines such as a VDD line PL1, a Vini line PL2, and a VSS line PL3 (see also FIG. 6). The pixel array includes a display area DA in which images are displayed together in a display mode. The pixel array can be divided into a circuit layer 600, a light emitting element 610, and a sensor layer 620 as shown in FIG. 1. The screen on which the input images are displayed on the substrate 100 includes the display area DA. A controller 500 can be provided.

Each sub-pixel of the display pixel in the display area DA includes a pixel circuit. The pixel circuit can include a driving element for supplying a current to the light emitting element OLED, a plurality of switch elements for sampling a threshold voltage of the driving element and switching a current path of the pixel circuit, and a capacitor for maintaining a gate voltage of the driving element. The pixel circuit and a photosensor driving circuit can be disposed under the light emitting element OLED.

The display panel driver writes pixel data of the input images to the display pixels P. The display panel driver includes a data driver 306 for supplying a data voltage of the pixel data to the data lines DL, and a gate driver 150 for sequentially supplying gate pulses to the gate lines GL. The data driver 306 can be integrated into a drive IC 300. The display panel driver can further include a touch sensor driver. The data driver 306 can be integrated into the drive IC 300 along with a timing controller 303.

The drive IC 300 can include a data reception and operation unit 308, the timing controller 303, the data driver 306, a gamma compensation voltage generator 305, a power unit 304, a second memory 302, etc. The drive IC 300 can be connected to a host system 200, a first memory 301, and the substrate 100.

The drive IC 300 can be bonded onto the substrate 100. The drive IC 300 can receive pixel data and a timing signal of the input image from the host system 200, supply a data voltage of the pixel data to the display pixels through the data lines DL, and synchronize the data driver 306 and the gate driver 150.

The drive IC 300 can be connected to the data lines DL through data output channels to supply the data voltage of the pixel data to the data lines DL. The drive IC 300 can output a gate timing signal for controlling the gate driver 150 through gate timing signal output channels. The gate timing signal generated from the timing controller 303 can include a gate start pulse (VST), a gate shift clock (CLK), etc. The gate start pulse (VST) and the gate shift clock (CLK) swing between a gate-on voltage (VGL) and a gate-off voltage (VGH). The gate timing signals (VST and CLK) output from a level shifter 307 are applied to the gate driver 150 to control a shift operation of the gate driver 150.

The gate driver 150 can include a shift register formed on an upper circuit layer of the substrate 100 along with the pixel array. The shift register of the gate driver 150 sequentially supplies gate signals to the gate lines GL under the control of the timing controller 303. The gate signal includes a scan pulse and an EM pulse applied to the pixel circuit, and an exposure signal (TG) applied to the photo sensor driving circuit. The shift register can include a scan driver for outputting the scan pulse and an EM driver for outputting the EM pulse. GVST and GCLK are gate timing signals input to the scan driver. EVST and ECLK are gate timing signals input to the EM driver.

The data reception and operation unit 308 includes a reception unit for receiving the pixel data input as a digital signal from the host system 200, and a data operation unit that improves image quality by processing the pixel data input through the reception unit. The data operation unit can include a data restoration unit for decoding and restoring the compressed pixel data and an optical compensation unit for adding a preset optical compensation value to the pixel data. The optical compensation value can be set as a value for correcting the luminance of each pixel data based on the luminance of the screen measured based on camera images captured during a manufacturing process.

The timing controller 303 can provide the pixel data of the input image received from the host system 200 to the data driver 306. The timing controller 303 can control the operation timing of the gate driver 150 and the data driver 306 by generating a gate timing signal for controlling the gate driver 150 and a source timing signal for controlling the data driver 306.

The data driver 306 can convert the pixel data (digital data) received from the timing controller 303 through a digital to analog converter (DAC) into a gamma compensation voltage and output the data voltage. The data voltage output from the data driver 306 can be supplied to the data lines DL of the pixel array through an output buffer connected to a data channel of the drive IC 300.

The gamma compensation voltage generator 305 can divide a gamma reference voltage from the power unit 304 through a voltage dividing circuit to generate a gamma compensation voltage for each grayscale. The gamma compensation voltage can be an analog voltage whose voltage is set for each grayscale of pixel data. The gamma compensation voltage output from the gamma compensation voltage generator 305 can be provided to the data driver 306.

The power unit 304 can use a DC-DC converter to generate the power required to drive the pixel array of the substrate 100, the gate driver 150, and the drive IC 300. The DC-DC converter can include a charge pump, a regulator, a buck converter, a boost converter, etc.

The power unit 304 can adjust a direct current input voltage from the host system 200 to generate direct current power such as the gamma reference voltage and the gate-on voltage (VGL), the gate-off voltage (VGH), a pixel driving voltage (VDD), a low potential power voltage (VSS), and an initialization voltage (VAR). The gamma reference voltage can be supplied to the gamma compensation voltage generator 305. The gate-on voltage (VGL) and the gate-off voltage (VGH) can be supplied to the level shifter 307 and the gate driver 150. Pixel power such as the pixel driving voltage (VDD), the low potential power voltage (VSS), and the initialization voltage (Vini) can be commonly supplied to the pixels P. The pixel driving voltage (VDD) can be set to a voltage higher than the low potential power voltage (VSS). The initialization voltage (Vini) can be set to a direct current voltage lower than the threshold voltage of the light emitting element (OLED), can initialize major nodes of the pixel circuits, and can suppress the light emission of the light emitting element (OLED). The initialization voltage (Vini) can be set to a voltage lower than the pixel driving voltage (VDD) and equal to or lower than the low potential power voltage (VSS).

The second memory 302 can store compensation values, register setting data, etc. received from the first memory 301 when power is input to the drive IC 300. The compensation values can be applied to various algorithms for improving image quality. The compensation values can include an optical compensation value. The register setting data can define the operations of the data driver 306, the timing controller 303, the gamma compensation voltage generator 305, etc. The first memory 301 can include a flash memory. The second memory 302 can include a static RAM (SRAM).

The host system 200 can be implemented as an application processor (AP). The host system 200 can transmit the pixel data of the input image to the drive IC 300 through a mobile industry processor interface (MIPI). The host system 200 can be connected to the drive IC 300 through, for example, a flexible printed circuit (FPC).

The display panel can be implemented as a flexible panel applicable to a flexible display. The size of a screen of the flexible display can be changed by winding, folding, or bending the flexible panel, and can be easily manufactured in various designs. The flexible display can be implemented as a rollable display, a foldable display, a bendable display, a slidable display, etc. The flexible panel can be manufactured as so-called a “plastic OLED panel.” The plastic OLED panel can include a back plate and a pixel array on an organic thin film bonded to the back plate. The back plate can be a polyethylene terephthalate (PET) substrate. The pixel array and a touch sensor array can be formed on an organic thin film substrate. The back plate can block moisture permeation toward the organic thin film to prevent the pixel array from being exposed to humidity. The organic thin film substrate can be a polyimide (PI) film substrate. A multi-layer buffer film can be formed on the organic thin film substrate using an insulating material. The circuit layer, the light emitting element, and a sensor layer can be stacked on the organic thin film.

In the display device of the present invention, the pixel circuit, the photosensor driving circuit, and the gate driver disposed on the circuit layer can include a plurality of transistors. The transistors can be an oxide thin film transistor (TFT) containing an oxide semiconductor or a low temperature poly silicon (LTPS) TFT including LTPS. Each of the transistors can be implemented as a p-channel TFT or n-channel TFT. In an embodiment, examples in which the transistors of the pixel circuit are implemented as p-channel TFTs are mainly described, but the present invention is not limited thereto.

A transistor is a three-electrode element including a gate, a source, and a drain. The source is an electrode for supplying carriers to the transistor. In the transistor, the carriers begin to flow from the source. The drain is an electrode from which the carriers exit the transistor. In the transistor, carriers flow from the source to the drain. In the case of an n-channel transistor, since the carriers are electrons, a source voltage is lower than a drain voltage so that the electrons can flow from the source to the drain. In the n-channel transistor, a direction of the current flows from the drain to the source. In the case of a p-channel transistor (PMOS), since the carriers are holes, the source voltage is higher than the drain voltage so that the holes can flow from the source to the drain. In the p-channel transistor, a current flows from the source to the drain because the holes flow from the source to the drain. It should be noted that the source and drain of the transistor are not fixed. For example, the source and the drain can be changed depending on an applied voltage. Therefore, the present invention is not limited by the source and drain of the transistor. In the following description, the source and drain of the transistor are referred to as “first and second electrodes.”

The gate pulse can swing between a gate-on voltage and a gate-off voltage. The gate-on voltage can be set to a voltage higher than a threshold voltage of the transistor, and the gate-off voltage can be set to a voltage lower than the threshold voltage of the transistor. The transistor can be turned on in response to the gate-on voltage and turned off in response to the gate-off voltage. In the case of the n-channel transistor, the gate-on voltage can be a gate high voltage (VGH) and the gate-off voltage can be a gate low voltage (VGL). In the case of the p-channel transistor, the gate-on voltage can be the gate low voltage (VGL) and the gate-off voltage can be the gate high voltage (VGH).

FIG. 3 is a cross-sectional view showing a cross-sectional structure of a sub-pixel in a display panel according to an embodiment of the present disclosure.

Referring to FIG. 3, the sub-pixel can include a driving transistor DT that drives the light emitting element, a first switch transistor T1 that applies a voltage to the charge generating layer, and the thin film transistors DT and T1 can include light blocking layers 111A and 111B, respectively, disposed on the substrate 100. The light blocking layers 111A and 111B can include a metal material such as molybdenum (Mo), titanium (Ti), or copper (Cu) and can be formed of a single layer or multiple layers of these materials. But embodiments of the present disclosure are not limited thereto.

A buffer insulating film 101 can be located on upper and side surfaces of the light blocking layers 111A and 111B and an entire surface of the substrate 100 on which the light blocking layers 111A and 111B are not formed. The buffer insulating film 101 can prevent contamination by the substrate 100 in subsequent processes. The buffer insulating film 101 can include an insulating material. For example, the buffer insulating film 101 can include a silicon oxide (SiOₓ) material and/or a silicon nitride (SiNₓ) material. But embodiments of the present disclosure are not limited thereto. For example, the silicon oxide (SiOₓ) material can include silicon dioxide (SiO₂). The buffer insulating film 101 can have a multi-layer structure. But embodiments of the present disclosure are not limited thereto.

A semiconductor pattern 112A of the driving transistor DT connected to a first electrode 120 of the sub-pixel, a semiconductor pattern 112B of the first switch transistor T1 connected to a second electrode 121, a gate insulating film 102, gate electrodes 114A and 114B, an interlayer insulating film 103, source electrodes 115A and 115B, and drain electrodes 116A and 116B can be formed on the buffer insulating film 101.

The first electrode 120 can be an anode electrode, and the anode electrode 120 can be formed of a transparent conductive material. For example, the anode electrode 120 can be formed of ITO and IZO. But embodiments of the present disclosure are not limited thereto.

The second electrode 121 can be a charge generating layer CGL control electrode (CGL electrode) of a sub-pixel.

The semiconductor patterns 112A and 112B can include metal oxides such as IGZO and can overlap the light blocking layers 111A and 111B.

Each of the semiconductor patterns 112A and 112B can include a source area, a drain area, and a channel area. The source area and the drain area can be made to be conductive and can be connected to the source electrodes 115A and 115B and the drain electrodes 116A and 116B.

The gate insulating film 102 can be located on the semiconductor pattern 112 (which includes semiconductor patterns 112A and 112B). The gate insulating film 102 can extend outside the semiconductor pattern 112. For example, side surfaces of the semiconductor pattern 112 and an upper part of the buffer insulating film 101 on which the semiconductor pattern 112 is not formed can be covered by the gate insulating film 102. But embodiments of the present disclosure are not limited thereto.

The gate insulating film 102 can include an insulating material. For example, the gate insulating film 102 can include a silicon oxide (SiOₓ) material and/or a silicon nitride (SiNₓ) material. But embodiments of the present disclosure are not limited thereto. The gate insulating film 102 can include a material having a high dielectric constant (High-K material). But embodiments of the present disclosure are not limited thereto.

The gate electrodes 114A and 114B can be located on the gate insulating film 102. The gate electrodes 114A and 114B can overlap the channel areas of the semiconductor patterns 112A and 112B. For example, the gate electrodes 114A and 114B can be insulated from the semiconductor patterns 112A and 112B by the gate insulating film 102.

The gate electrodes 114A and 114B can include a conductive material. The gate electrodes 114A and 114B can include a hydrogen barrier material. The hydrogen barrier material can include a hydrogen storage material and a hydrogen barrier material. For example, the gate electrodes 114A and 114B can include titanium (Ti) or tantalum (Ta). In addition, the gate electrodes 114A and 114B can include a metal material with low resistance. For example, the gate electrodes 114A and 114B can include molybdenum (Mo), copper (Gu), aluminum (Al), etc., and can be formed of a single layer or multiple layers of these materials. But embodiments of the present disclosure are not limited thereto.

The interlayer insulating film 103 can be located on the gate insulating film 102 and the gate electrode 114 (which includes gate electrodes 114A and 114B). The interlayer insulating film 103 can include an insulating material. For example, the interlayer insulating film 103 can include a silicon oxide (SiOₓ) material and/or a silicon nitride (SiNₓ) material. But embodiments of the present disclosure are not limited thereto. For example, the silicon oxide (SiOₓ) material can include silicon dioxide (SiO₂). The interlayer insulating film 103 can have a multi-layer structure. But embodiments of the present disclosure are not limited thereto.

The source electrodes 115A and 115B and the drain electrodes 116A and 116B can be located on the interlayer insulating film 103. The source electrodes 115A and 115B and the drain electrodes 116A and 116B can be electrically connected to the source area and drain area of the semiconductor pattern 112. The source electrodes 115A and 115B and the drain electrodes 116A and 116B can include a metal such as aluminum (Al), chromium (Cr), molybdenum (Mo), tungsten (W), and copper (Cu), but the embodiments of the present disclosure are not limited thereto.

An overcoat layer 104 can be located on the interlayer insulating film 103. The overcoat layer 104 can remove steps generated by the thin film transistors in order to prevent an external impact and to planarize a light emitting area. The overcoat layer 104 can extend along the interlayer insulating film 103 to cover the thin film transistors.

The overcoat layer 104 can include an insulating material. The overcoat layer 104 can include a material different from the interlayer insulating film 103. The overcoat layer 104 can include a material with relatively high fluidity. For example, the overcoat layer 104 can include an organic insulating material. But embodiments of the present disclosure are not limited thereto.

The anode electrode 120 can be located on the overcoat layer 104. The anode electrode 120 can be formed of a transparent conductive material. For example, the anode electrode 120 can be formed of ITO and IZO. But embodiments of the present disclosure are not limited thereto. Alternatively, the anode electrode 120 can be formed of an alloy or multi-layer of a material including silver (Ag), manganese (Mg), and ytterbium (Yb), but the embodiments of the present disclosure are not limited thereto.

The anode electrode 120 can be connected to the drain electrode 116 (which includes drain electrodes 116A and 116B) of the driving thin film transistor in the sub-pixel and can be located in the light emitting area. For example, the interlayer insulating film 103 and the overcoat layer 104 can include a pixel contact hole that partially exposes the drain electrode 116A of the driving transistor DT in the sub-pixel. The anode electrode 120 can include an area that overlaps the drain electrode 116A. Accordingly, in the display panel according to the embodiment of the present disclosure, a driving current can be supplied to the anode electrode 120 by the driving thin film transistor.

A bank layer 105 can be formed on a portion except for light emitting areas of the red sub-pixel, green sub-pixel, and blue sub-pixel on the anode electrode 120. The bank layer 105 can be formed of an organic insulating material, and can be formed of a transparent or black organic insulating material. But embodiments of the present disclosure are not limited thereto. The CGL electrode 121 can be located on the bank layer 105. The CGL electrode 121 can be formed of an alloy or multi-layer of a material including silver (Ag), manganese (Mg), and ytterbium (Yb), and the embodiments of the present disclosure are not limited thereto.

The CGL electrode 121 can be connected to the drain electrode 116B of the first switch transistor T1 and can be located in a non-light emitting area. The overcoat layer 104 and the bank layer 105 can include a contact hole that partially exposes the drain electrode 116B of the first switch transistor T1. The CGL electrode 121 can include an area that overlaps the drain electrode 116B. Therefore, in the display panel according to the embodiment of the present disclosure, it is possible to supply the CGL control voltage (Vcgl) generated by the thin film transistor to the charge generating layer CGL.

In various embodiments of the present disclosure, the CGL electrode 121 can include the same material as the anode electrode 120, but embodiments of the present disclosure are not limited thereto, and the CGL electrode 121 can include a different material from that of the anode electrode 120. For example, the CGL electrode 121 can be formed of a transparent conductive material, and can include ITO and IZO. But embodiments of the present disclosure are not limited thereto. Alternatively, the CGL electrode 121 can be formed of an alloy or multi-layer of a material including silver (Ag), manganese (Mg), and ytterbium (Yb), but the embodiments of the present disclosure are not limited thereto.

In various embodiments of the present disclosure, the CGL electrode 121 can be located where the bank layer 105 exposes the overcoat layer 104. For example, the CGL electrode 121 can be located on a surface of the overcoat layer 104, and can be coplanar with the anode electrode 120. Alternatively, the bank layer 105 can be thinner at a location over the first switch transistor T1, so that an upper surface of the CGL electrode 121 can be located at an intermediate location between the surface of the overcoat layer 104 and an uppermost surface of back layer 105, but the embodiments of the present disclosure are not limited thereto. An organic light emitting element layer 122 and a third electrode 123 can be formed on the bank layer 105 and the anode electrode 120. The third electrode 123 can be formed as a common layer. The organic light emitting element layer 122 can generate light with a luminance corresponding to the voltage difference between the anode electrode 120 and the third electrode 123.

The third electrode 123 can be a cathode electrode, and the cathode electrode 123 can include a conductive material. The cathode electrode 123 can include a material different from the anode electrode. The cathode electrode 123 can include a metal with a relatively high reflectivity and can be formed of silver (Ag), gold (Au), aluminum (Al), magnesium (Mg), or silver-magnesium (Ag: Mg), or a single layer thereof or an alloy thereof, but is not limited thereto. The alloy can be, for example, an aluminum alloy (Al alloy), but is not limited thereto.

A capping layer 124, a first encapsulation layer 110, and a second encapsulation layer 111 can be located on the cathode electrode 123 to prevent damage to the organic light emitting element layer due to external impacts and moisture.

The capping layer 124 can be formed of a thin metal layer including aluminum (Al) or an organic material, the first encapsulation layer 110 can be formed of epoxy and an olefin as an encapsulation layer that can prevent moisture permeation, and the second encapsulation layer 111 can be formed of a metal layer including iron (Fe) and nickel (Ni). But embodiments of the present disclosure are not limited thereto.

With reference to FIG. 3, the upper surface of the CGL electrode 121 can be located higher than an upper surface of the third electrode 123 and/or an upper surface of the capping layer 124 at an area overlapping the first electrode 120, but embodiments of the present disclosure are not limited thereto. For example, the upper surface of the CGL electrode 121 can be located between the upper surface of the first electrode 120 and the upper surface of the third electrode 123 or the upper surface of the capping layer 124. In other embodiments of the present disclosure, the CGL electrode 121 can be located below an upper surface of the overcoat layer 104.

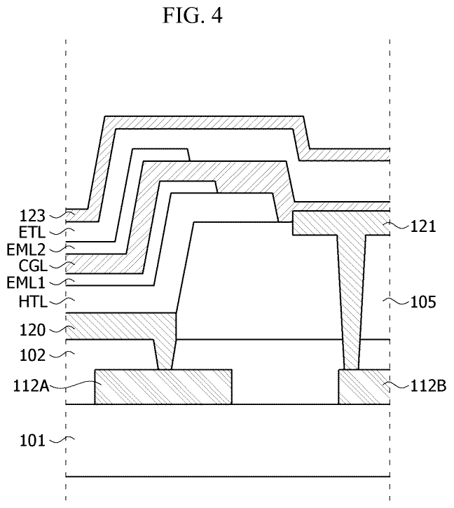

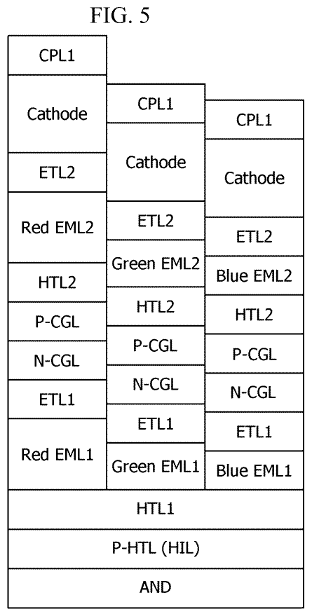

FIG. 4 is a circuit diagram showing in detail a cross-sectional structure of an organic light emitting element according to an embodiment of the present disclosure. FIG. 5 is a cross-sectional view showing in detail a tandem structure of an organic light emitting element for each sub-pixel according to an embodiment of the present invention.

Referring to FIGS. 4 and 5, the organic light emitting element layer of the present invention can be formed in a tandem structure composed of a plurality of light emitting portions between the anode electrode 120 and the cathode electrode 123. The organic light emitting element layer of the present invention can be disposed on the anode electrode 120 in the order of a first hole injection layer HIL, a first hole transport layer HTL1, a first light emitting layer EML1, a first electron transport layer ETL1, and a charge generating layer CGL, a second hole transport layer HTL2, a second light emitting layer EML2, and a second electron transport layer ETL2, and the cathode electrode 123 can be disposed on the second electron transport layer ETL2. In addition, an electron injection layer EIL can be additionally disposed between the second electron transport layer ETL2 and the cathode electrode 123.

The hole injection layer HIL is a layer that facilitates the injection of holes from the anode electrode 120 to the organic light emitting layer.

The hole transport layer HTL is an organic layer that can smoothly transport holes from the hole injection layer HIL to the organic light emitting layer. The hole transport layer HTL, for example, can be formed of one or more of materials of NPD (N,N′-bis(naphthalene-1-yl)-N,N′-bis(phenyl)-2,2′-dimethylbenzidine), TPD(N,N′-bis-(3-methylphenyl)-N,N′-bis(phenyl)-benzidine), s-TAD(2,2′,7,7′-tetrakis(N,N-dimethylamino)-9,9-spirofluorene), and MTDATA (4,4′,4″-tris(N-3-methylphenyl-N-phenyl-amino)-triphenylamine), but is not limited thereto.

The electron transport layer ETL transports electrons supplied from the cathode electrode 123 to the organic light emitting layer.

The electron injection layer EIL that can smoothly inject electrons from the cathode electrode 123 into the organic light emitting layer can be disposed between the cathode electrode 123 and the electron transport layer ETL.

When a voltage is applied to the anode electrode 120 and cathode electrode 123 of the OLED, holes passing through the hole transport layer HTL and electrons passing through the electron transport layer ETL can move to the light emitting layer to form excitons, resulting in visible light being emitted from the light emitting layers EML1 and EML2.

The electron transport layer ETL can be disposed on an upper part of the electron injection layer EIL and can receive electrons from the electron injection layer. The electron transport layer can deliver the supplied electrons to the organic light emitting layer.

The first hole injection layer HIL, the first hole transport layer HTL1, the first light emitting layer EML1, and the first electron transport layer ETL1 are defined as a first light emitting portion, and the second hole transport layer HTL2, the second light emitting layer EML2, and the second electron transport layer ETL2 can be defined as a second light emitting portion. The first light emitting layer EML1 of the first light emitting portion and the second light emitting layer EML2 of the second light emitting portion can emit light in the same wavelength range and emit light of substantially the same color to the outside of the display panel. Without being limited thereto, the first light emitting layer EML1 and the second light emitting layer EML2 can emit light of different wavelength ranges to emit light of a target wavelength range to the outside of the display panel by combining the light emitted from the two light emitting layers EML1 and EML2.

The charge generating layer CGL can be provided as a single layer between the first light emitting portion and the second light emitting portion, but can be formed of a double layer of an N-type charge generating layer N-CGL and a P-type charge generating layer P-CGL for hole inflow from a lower stack to an upper stack and electron inflow from the upper stack to the lower stack. The charge generating layer CGL can be disposed between the first light emitting portion and the second light emitting portion to control a charge balance of the first light emitting portion and the second light emitting portion. The charge generating layer CGL can serve to generate holes and electrons and inject the holes and electrons into the first light emitting portion and second light emitting portion.

The N-type charge generating layer N-CGL can be formed of an organic layer in which a host is doped with an alkali metal such as lithium (Li), sodium (Na), potassium (K), or cesium (Cs), or an alkaline earth metal such as magnesium (Mg), strontium (Sr), barium (Ba), or radium (Ra), but is not limited thereto. In addition, the P-type charge generating layer P-CGL can be composed of at least one host and at least one P-type dopant. For example, the P-type dopant can include at least one material of F₄-TCNQ (2,3,5,6-tetrafluoro-7,7,8,8-tetracyano-quinodimethane), FeCl₃, FeF₃, and SbCl₅, but is not limited thereto. Further, for example, the host can include at least one material of NPB (N,N′-bis(naphthalen-1-yl)-N,N′-bis(phenyl)-benzidine), TPD(N,N′-bis(3-methylphenyl)-N,N′-bis(phenyl)-benzidine), and TNB(N,N,N′,N′-tetra-naphthalenyl-benzidine), but is not limited thereto.

The CGL electrode 121 can be formed on the bank layer 105 and can electrically connect the first switch transistor T1 and the charge generating layer CGL through a contact hole. The CGL electrode 121 can apply a voltage to the charge generating layer CGL in a black state or a low grayscale situation in which an image is not displayed on the display device. The sub-pixels can emit light with a luminance corresponding to a grayscale value of the pixel data. The luminance of the sub-pixel can be divided into low grayscale luminance that is equal to or less than a preset reference value and high grayscale luminance that is greater than the reference value. The reference value for distinguishing between low grayscale and high grayscale can be determined based on an image quality evaluation test.

With reference to FIG. 4, the charge generating layer CGL can be exposed when at least one of the first light emitting layer EML1 and the second light emitting layer EML2 is truncated over the bank layer 105. An exposed portion of the charge generating layer CGL can extend to electrically contact the CGL electrode 121. In various embodiments of the present disclosure, the one or more of the anode electrode 120, the first hole injection layer HIL, the first hole transport layer HTL1, the first light emitting layer EML1, the first electron transport layer ETL1, the second hole transport layer HTL2, the second light emitting layer EML2, and the second electron transport layer ETL2, and the cathode electrode 123 can be electrically or physically insulated from the CGL electrode 121. For example, with reference to FIG. 4, the first hole transport layer HTL can be separated from the CGL electrode 121 and a portion of the charge generating layer CGL can be located between the CGL electrode 121 and the first hole injection layer HIL. Also, the first light emitting layer EML1 and the second light emitting layer EML2 can be separated from the CGL electrode 121 and a portion of the charge generating layer CGL can be located between the CGL electrode 121 and the first light emitting layer EML1 and the second light emitting layer EML2. Additionally, the third electrode 123 can be separated from the CGL electrode 121, so that the electron transport layer ETL and/or the portion of the charge generating layer CGL can be interposed between the third electrode 123 and the CGL electrode 121. In various embodiments of the present disclosure, a recess can be located in the bank layer 105, and one or more of the anode electrode 120, the first hole injection layer HIL, the first hole transport layer HTL1, the first light emitting layer EML1, the first electron transport layer ETL1, the second hole transport layer HTL2, the second light emitting layer EML2, and the second electron transport layer ETL2, and the cathode electrode 123 can be located in the recess.

A detailed description of the situation in which a voltage is applied is described below.

The stacked structure of the red, green, and blue light emitting elements can be formed the same, but the thickness of the light emitting layer of each light emitting element can be formed differently, and as a result, the red, green, and blue light emitting elements can be stacked and disposed with different thicknesses. The stacked structure of the organic light emitting element applied to the present invention is not limited thereto, and any stacked structure of organic light emitting elements in a tandem structure can be used.

FIG. 6 is a pixel circuit view for driving of a display panel of the present disclosure.

Referring to FIG. 6, the pixel circuit can include a light emitting element disposed in a tandem structure and divided into a first light emitting portion OLED1 and a second light emitting portion OLED2, a charge generating layer CGL disposed between the first light emitting portion and the second light emitting portion, a driving transistor DT for supplying a current to a light emitting element, and a first switch transistor T1 for supplying a CGL control current to the CGL electrode 121 in a low grayscale situation.

An anode electrode 120 of the light emitting element can be connected to a first node N1, and a cathode electrode 123 can be connected to a second constant voltage line to which a low potential reference voltage VSS is connected. The CGL electrode 121 of the light emitting element can be connected to the first switch transistor T1.

The first node N1 can be connected to the anode electrode 120 of the light emitting element, a first electrode of the driving transistor DT, and a storage capacitor. The storage capacitor can be connected between the first node N1 and a second node N2.

The driving transistor DT includes a gate electrode connected to the second node N2, the first electrode connected to the first node N1, and a second electrode connected to a first constant voltage line to which the pixel drive voltage VDD is applied, and supplies the pixel drive voltage VDD to the anode electrode 120 of the light emitting element in response to a signal from the gate electrode.

The first switch transistor T1 can include a gate electrode connected to a CGL gate signal Gcgl line, a first electrode connected to the CGL electrode 121, and a second electrode connected to a CGL control voltage line, and can be turned on with the CGL gate signal Gcgl to supply the CGL control voltage Vcgl to the CGL electrode 121.

A second switch transistor T2 can include a gate electrode connected to a gate signal line, a first electrode connected to the second node N2, and a second electrode connected to a data voltage line, and can supply a data voltage to the second node N2 in response to the gate signal.

The second node N2 can be connected to the gate electrode of the driving transistor DT, the first electrode of the second switch transistor T2, and the storage capacitor.

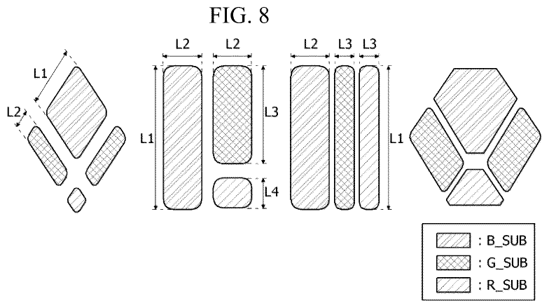

Flashing can be visible to a user when the display panel changes the grayscale in low grayscale images, as shown in the example of FIG. 7. The present invention can control the potential of the charge generating layer to the potential between an anode voltage and a cathode voltage of the light emitting element so that the flashing is not visible in the low grayscale image as shown in FIG. 7.

FIG. 7 is a view showing an example of a voltage applied to a light emitting element.

Referring to FIG. 7, when the grayscale changes from a low grayscale image to a gray or medium image, an anode voltage increases. In this case, an intermediate voltage can be applied to the CGL electrode so that a voltage of the charge generating layer increases along with the anode voltage to become an intermediate voltage between the anode voltage and the cathode voltage.

The CGL electrode can be formed on the bank layer 105 as shown in FIGS. 3 and 4 to apply a CGL control voltage supplied from the first switch transistor T1 to the charge generating layer through a contact hole.

In order to prevent the flashing phenomenon, it is necessary to make the potential applied to the first light emitting portion and the voltage applied to the second light emitting portion the same. Therefore, in the case of a black state in which no image is displayed on the display panel, a potential difference between the first light emitting layer and the CGL electrode and a potential difference between the second light emitting layer and the CGL electrode can be made equal by applying an intermediate value (Vcgl1) between an initialization voltage VAR and a low potential reference voltage VSS to the CGL electrode. For example, the Vcgl1 can be a value that is about half of the a potential difference between the first light emitting layer and the second light emitting layer, but embodiment of the present disclosure are not limited thereto.

Then, in the case of displaying a low grayscale image, the potential difference between the first light emitting layer and the CGL electrode and the potential difference between the second light emitting layer and the CGL electrode can be made equal as well by applying the intermediate value (Vcgl2) between the data voltage Vdata applied to each sub-pixel and the low potential reference voltage VSS to the CGL electrode. For example, the Vcgl2 can be a value that is about half of the potential difference between the first light emitting layer and the second light emitting layer, but embodiment of the present disclosure are not limited thereto. For example, one or more of the intermediate value Vcgl1 or Vcg12 can be closer to the potential of the first light emitting layer or the potential of the second light emitting layer, but embodiments of the present disclosure are not limited thereto.

The intermediate value of the Vdata voltage for each sub-pixel applied to the CGL electrode can be set using the same logic as an optical compensation step that sets the Vdata voltage of the sub-pixel.

Since voltage values applied to the first light emitting layer and second light emitting layer can be made equal by applying the above arbitrary voltage to the CGL electrode, the flashing phenomenon in low grayscale can be prevented.

Preferably, the voltage applied to the CGL electrode can be controlled in all sub-pixels under a low grayscale situation, but the CGL control voltage can also be applied only to the green sub-pixel which has the greatest impact on luminance in terms of power consumption, etc.

The CGL control voltage can be applied to the CGL electrode regardless of low grayscale and high grayscale, but it is desirable to apply the CGL control voltage to the CGL electrode only in the case of the low grayscale image output to reduce power consumption because flashing phenomenon is not visible to the user in the case of high grayscale.

FIG. 8 is a plan view showing an example of light emitting areas for each color of sub-pixels according to various embodiments of the present disclosure.

Referring to FIG. 8, each sub-pixel includes a light emitting area from which light from a light emitting element is emitted. The shape and size of the light emitting area for each color can be designed in various ways. Due to differences in luminous efficiency for each color, a light emitting area of a blue sub-pixel B-SUB can be larger than light emitting areas of other colors.

The blue light emitting area B-SUB can be a square light emitting area with each side having a first length. A green light emitting area G-SUB can be disposed close to one side of the blue light emitting area B-SUB. Within one pixel, two green light emitting areas G-SUB can be disposed in a rectangular shape with a first length in the longitudinal direction and a second length shorter than the first length in the width direction. Within one pixel, sizes of the first and second green light emitting areas G-SUB can be smaller than a size of the blue light emitting area B-SUB. A red light emitting area R-SUB can be disposed in a square shape with each side having the second length.

The blue light emitting area B-SUB can be disposed in a rectangular shape with a first length in the longitudinal direction and a second length shorter than the first length in the width direction, and the green sub-pixel G-SUB can be disposed in a rectangular shape with a third length in the longitudinal direction and the second length in the width direction. The red light emitting area R-SUB can be disposed in a rectangular shape with a fourth length that is shortest in the longitudinal direction and the second length in the width direction.

The blue light emitting area B-SUB can be disposed in a rectangular shape with a first length in the longitudinal direction and a second length shorter than the first length in the width direction, and the green and red light emitting areas G-SUB and R-SUB can be disposed in a rectangular shape with the first length in the longitudinal direction and a third length shorter than the second length in the width direction.

The blue light emitting area B-SUB can be disposed in a hexagonal shape, the green light emitting area G-SUB in a rectangular shape, and the red light emitting area R-SUB in a hexagonal shape with a smaller cross-sectional area than the blue light emitting area B-SUB.

As described in FIG. 8, the sub-pixels can be disposed with various shapes and surface areas, but in general, the total surface area between the sub-pixels can be disposed to be equal or wider in the order of blue, green, and red.

According to the present disclosure, a display panel includes a substrate, a circuit layer disposed on the substrate, and a light emitting element layer disposed on the circuit layer and electrically connected to a pixel circuit of the circuit layer, wherein the light emitting element layer includes a first electrode and a second electrode electrically connected to the pixel circuit, a first light emitting layer, a charge generating layer, and a second light emitting layer stacked on the first electrode and the second electrode, and a third electrode disposed on the second light emitting layer, and the present disclosure discloses a display panel, which controls a flashing phenomenon by controlling the potential of the charge generating layer by connecting the charge generating layer control electrode in the charge generating layer.

Various and useful advantages and effects of the present invention are not limited to those mentioned above, and other effects not mentioned will be clearly understood by those skilled in the art from the following description.

Although embodiments of the present invention have been described in detail with reference to the accompanying drawings, the present invention is not limited to these embodiments, and various modifications can be made without departing from the technical spirit of the present invention. Therefore, the embodiments disclosed in the present invention are not intended to limit the technical spirit of the present invention, but intended to describe the same, and the scope of the technical spirit of the present invention is not limited by these embodiments. Therefore, it should be understood that the above-described embodiments are illustrative and not restrictive in all respects. The scope of protection of the present invention should be interpreted in accordance with the claims, and all technical ideas within the equivalent scope thereof should be interpreted as being included in the scope of rights of the present invention.

What is claimed is:

1. A display panel comprising:
a substrate;
a circuit layer disposed on the substrate; and
a light emitting element layer disposed on the circuit layer and electrically connected to a pixel circuit of the circuit layer,
wherein the light emitting element layer includes:
a first electrode and a second electrode electrically connected to the pixel circuit;
a first light emitting layer, a charge generating layer, and a second light emitting layer that are stacked on the first electrode; and
a third electrode disposed on the second light emitting layer, and
wherein the second electrode is configured to supply a voltage to the charge generation layer that is different from those supplied to the first electrode and the third electrode.

2. The display panel of claim 1, wherein the charge generating layer includes a double layer of an N-type charge generating layer and a P-type charge generating layer.

3. The display panel of claim 1, wherein the first electrode is an anode electrode,
wherein the second electrode is a charge generating layer control electrode, and
wherein the third electrode is a cathode electrode.

4. The display panel of claim 1, wherein the circuit layer includes a plurality of pixel circuits disposed in each of a plurality of sub-pixels,
wherein the first electrode is disposed in each of the plurality of sub-pixels,
wherein the light emitting element layer includes a bank layer disposed between first electrodes of neighboring sub-pixels, and
wherein the second electrode contacts the charge generating layer by passing through the bank layer.

5. The display panel of claim 1, wherein the circuit layer further includes:
a protective layer covering the pixel circuit; and
a planarization layer covering the protective layer,
wherein the light emitting element layer further includes:
a hole injection layer covering a portion of a bank layer disposed between the first electrode and first electrodes of neighboring sub-pixels;
a hole transport layer disposed on the hole injection layer; and
an electron transport layer covering the second light emitting layer and the charge generating layer, and
wherein the charge generating layer is separated on the bank layer between the neighboring sub-pixels.

6. The display panel of claim 1, wherein the first light emitting layer emits light of substantially a same color as the second light emitting layer.

7. The display panel of claim 5, wherein the second electrode is on the bank layer.

8. The display panel of claim 1, wherein the first electrode and the second electrode include a same material.

9. The display panel of claim 1, further comprising a bank layer on the first electrode,
wherein the second electrode is on the bank layer.

10. A pixel circuit comprising:
a light emitting element including a first light emitting layer, a charge generating layer, and a second light emitting layer that are stacked, and further including a first electrode disposed under the first light emitting layer, a second electrode electrically connected to the charge generating layer, and a third electrode to which a cathode voltage is applied;
a driving transistor configured to supply a current for driving the first light emitting layer and the second light emitting layer of the light emitting element according to a gate-source voltage;
a first switch transistor electrically connected to the second electrode; and
a second switch transistor configured to supply an anode reset voltage to the first electrode in response to an anode reset voltage signal.

11. The pixel circuit of claim 10, wherein the first electrode is an anode electrode,
wherein the second electrode is a charge generating layer control electrode, and
wherein the third electrode is a cathode electrode.

12. The pixel circuit of claim 10, wherein an overall grayscale of pixel data includes a low grayscale image in which a luminance value of the light emitting element is equal to or less than a preset reference value, and a high grayscale image in which the luminance value is greater than the reference value.

13. The pixel circuit of claim 11, wherein the first switch transistor supplies an intermediate voltage, which is lower than a voltage of the anode electrode and is higher than the cathode voltage, to the charge generating layer control electrode in response to a charge generating layer gate signal.

14. The pixel circuit of claim 10, wherein, while the anode reset voltage is supplied to the first electrode, the light emitting element is turned off and is in a non-emitting state, and
wherein, in the non-emitting state, the first switch transistor is turned on, and an intermediate voltage, which is lower than a voltage of the anode electrode and is higher than the cathode voltage, is applied to the second electrode.

15. The pixel circuit of claim 10, wherein in a low grayscale display mode in which the light emitting element emits light, the first switch transistor is turned on, and an intermediate value of a data voltage and a low potential reference voltage of the light emitting element is applied to the charge generating layer.

16. The pixel circuit of claim 10, wherein in a high grayscale display mode in which the light emitting element emits light, the first switch transistor is turned off.

17. The pixel circuit of claim 10, wherein the second electrode and the first switch transistor are included in at least a green sub-pixel of the pixel circuit.

18. The pixel circuit of claim 13, wherein the intermediate voltage is about half of a voltage difference between the voltage of the anode electrode and the cathode voltage.

19. A display panel comprising a plurality of pixel circuits each being the pixel circuit according to claim 10.

20. A display panel comprising:
a driving transistor disposed on a substrate;
a switching transistor disposed on the substrate; and
a light emitting element layer on the substrate,
wherein the light emitting element layer includes:
a first electrode connected to the driving transistor,
a first light emitting layer, a charge generating layer, and a second light emitting layer that are stacked on the first electrode,
a second electrode electrically connected to the charge generating layer, and
a third electrode on the second light emitting layer, and
wherein the second electrode is connected to the switching transistor and is configured to supply a voltage to the charge generation layer that is different from a voltage supplied to at least one of the first electrode and the third electrode.
